(19) United States
(12) Patent Application Publication
(10) Pub. No.: US 2002/0130680 A1
(43) Pub. Date: Sep. 19, 2002

(54) Method and apparatus for terminating emitter coupled logic (ECL) transceivers

(76) Inventors: Bruce Alan Meyer, Taylorsville, UT (US); Ralph Edward Carson, Woods Cross, UT (US); Philip Ross Wellington, Murray, UT (US)

Correspondence Address: PERMAN & GREEN, 425 POST ROAD, FAIRFIELD, CT, 06430, US

(21) Appl. No.: 09/809,235

(22) Filed: Mar. 15, 2001

(51) Int. Cl. H03K 19/003

(52) U.S. Cl. 326/30

(57) ABSTRACT

A device for changing a termination voltage of a differential data bus having a first and second data bus. The device comprises a first adjustable termination path connectable to the first data bus and a second adjustable termination path connectable to the second data bus. The device further comprises a switch connectable in parallel with the first adjustable termination path and the second adjustable termination path.

The U.S. Government has a paid-up license in this invention and the right in limited circumstances to require the patent owner to license others on reasonable terms as provided for by the terms of contract number FO9604-99-C-0011 awarded by United States Army.

### BACKGROUND OF THE INVENTION

1. Field of the Invention

The present invention relates to differential ECL bus to Transistor Transistor Logic (TTL) bus transceivers and, more particularly, to bus modal termination of such transceivers.

2. Prior Art

Propagation of signals on transmission lines and data buses is well known. Moreover, the undesirable effects due to un-terminated or improperly terminated signals is also well known. As is known, an un-terminated transmission line will have approximately twice the voltage at the un-terminated end as it does at the transmitting end. To prevent this doubling of the voltage, transmission lines are commonly terminated with a passive termination device having an impedance that substantially matches that of the transmission line. For example, if the transmission line has an impedance of 50 ohms, the passive termination device will be a 50 ohm resistor.

Virtually all types of circuits are susceptible to transmission line effects. For example, transmission line effects occur in telecommunications transmissions over a wire line path, in computer networks, and within printed circuit boards. In each of these circuits, the transmission line is terminated with an impedance that substantially matches the impedance of the transmission line to prevent the doubling of the original signal. In the design and implementation of electronic systems (such as digital computers, consumer/commercial electronic devices, or the like), particularly those employing integrated circuits, undesired transmission line effects are of a particular concern. As signals propagated on transmission lines, e.g., traces on a printed circuit board, reflections may occur on the lines. The reflections are due to, for example, mismatched impedances between the driver circuit and the line, which may cause the signal to reflect back and forth, giving rise to undesirable ringing. Ringing and other undesired transmission line effects, such as electromagnetic interference (EMI) are often exacerbated as the operating speed or frequency of the signal increases. It is known to use termination devices, or terminators, to reduce the propagation of reflections or standing waves inside the data cable. Terminators are used, and most often required, in a small computer systems interface (SCSI) bus. It is further known that certain multi-mode semi-conductor devices must be properly terminated in order to function correctly for the selected mode.

Implementation of high speed ECL transmission lines requires two components. The first component requires a negative voltage source and a resistor (pull down) and the second component is a matched line termination at the end of the transmission line.

Referring to FIG. 2C there is shown an ECL transmission line where the pull down network and the transmission line termination is accomplished with R1. R1 is chosen such that pull down current is adequate and the resistance is close to the transmission line impedance.

Referring now to FIG. 2D there is shown another implementation of a differential ECL line. The pull down network VEE,R1 is located at near the source and R2 is chosen to match the impedance of the transmission line.

Referring now to FIG. 2E there is shown a bi-directional differential transmission line. R1 is chosen to match the transmission impedance and the drivers are selected to drive an R1/2 load.

It can be readily appreciated that in order to use one of the configurations shown in FIG. 2C-FIG. 2E a physical reconfiguration of the pull down network and termination resistors is required. This is illustrated by referring to FIG. 2B where there is shown a 1-bit differential ECL Bus/TTL Bus transceiver as provided in a typical semiconductor package 10. As seen, U5 may receive and translate ECL data from an ECL data bus to a TTL data bus or U6 may receive and translate TTL data from the TTL data bus to be transmitted on the ECL data bus. However, for U6 to transmit ECL data on the ECL data bus and U5 to receive ECL data from the ECL data bus the proper transmit or receive differential terminations must be connected to the differential data bus. Referring now to FIG. 2A there is shown a TTL-ECL-TTL circuit. Element pairs U1/U3 and U2/U4 each form the 1-bit differential ECL Bus/TTL Bus transceiver as provided in a typical semi-conductor package. The appropriate terminations are shown in order for U1 to function as a transmitter and U2 to function as a receiver. Resistors R1 and R2, each 50 ohms, provide a pull up path to a −2vdc source for transmitter U1. Resistors R3 and R4, connected in series between the differential lines terminates the transmission lines with an impedance that substantially matches the characteristic impedance of the transmission lines. The disadvantages of fixed terminations R1/R2/−2vdc, R3/R4 and the disadvantage of the fixed connections of U1/U3, U2/U4 preclude U3 acting as a receiver and U4 acting as a transmitter. As a result transmission from the TTL2 data bus to the TTL 1 data bus would not be possible unless the terminations are physically changed. In general such a change would require reworking the circuit to add or remove resistors and change connections. Therefore a need exists for a method and apparatus that provides control of reconfigurable terminations for ECL Bus/TTL Bus transceivers. It is further known that the effectiveness of a line terminator is indirectly proportional to the distance between the location of the terminator and the end of the transmission line. Therefore, in the case of integrated circuits such as the transceiver described above, a need exists for a method and apparatus that provides control of reconfigurable terminations on board the integrated circuit.

### SUMMARY OF THE INVENTION

In accordance with one embodiment of the invention, a device for changing a termination voltage of a differential data bus having a first and second data bus is provided. The device comprises a first adjustable termination path connectable to the first data bus and a second adjustable termination path connectable to the second data bus. The device further comprises a switch connectable in parallel with the first adjustable termination path and the second adjustable termination path.

In accordance with another embodiment, the invention includes a method for changing terminations in an emitter coupled logic (ECL) transceiver having a differential data bus. The method comprises the steps of connecting a variable termination to the differential data bus having a first and second data bus, enabling a first termination path when the ECL transceiver is in a receive mode, and enabling two second termination paths when the ECL transceiver is in a transmit mode.

The invention is also directed to an apparatus for changing terminations in an emitter coupled logic (ECL) transceiver having a differential data bus. The apparatus comprises a variable termination connectable to the differential data bus. The variable termination comprises a first termination path or two second termination paths.

In accordance with another embodiment of the invention a device for changing a termination voltage of a differential data bus is provided. The differential data bus comprises a first and second data bus. The device comprises a resistive circuit connecting the first and second data buses to each other and a switch circuit located between the resistive circuit and a negative voltage source. The switch circuit has a connection point with the resistive circuit between two resistors of the resistive circuit, and the switch circuit is operable to selectively connect the first and second data buses, respectively through individual ones of the two resistors, to the negative voltage source.

In accordance with another embodiment of the invention a program storage device readable by a machine, tangibly embodying a program of instructions executable by the machine to perform method steps for changing terminations in a programmable logic device (PLD) having a multi-mode differential data bus is provided. The method comprises the steps of connecting a variable termination to the differential data bus, wherein the variable termination is a first termination path or two second termination paths; enabling the first termination path when the PLD is in a receive mode; or enabling the two second termination paths when the PLD is in a transmit mode.

### BRIEF DESCRIPTION OF THE DRAWINGS

The foregoing aspects and other features of the present invention are explained in the following description, taken in connection with the accompanying drawings, wherein:

FIG. 1 is a pictorial diagram of an embodiment of a synchronized command link system incorporating features of the present invention;

FIG. 2A is a schematic diagram showing a TTL-ECL-TTL 1-bit transceiver data bus architecture;

FIG. 2B is a schematic diagram of a typical TTL-ECL 1-bit transceiver;

FIG. 2C is a schematic diagram of an ECL transmission line with a resistor providing the dual function of pull down network and transmission line termination;

FIG. 2D is a schematic diagram of an ECL transmission line with a pull down network spatially separated from the corresponding transmission line termination;

FIG. 2E is a schematic diagram of an bi-directional differential transmission line with the dual function resistor of FIG. 2C;

FIG. 3 is a schematic diagram incorporating features of the present invention; and

FIG. 4 is a flow chart of one method for using the invention to select the correct termination of the ECL differential data bus.

### DETAILED DESCRIPTION OF THE PREFERRED EMBODIMENT

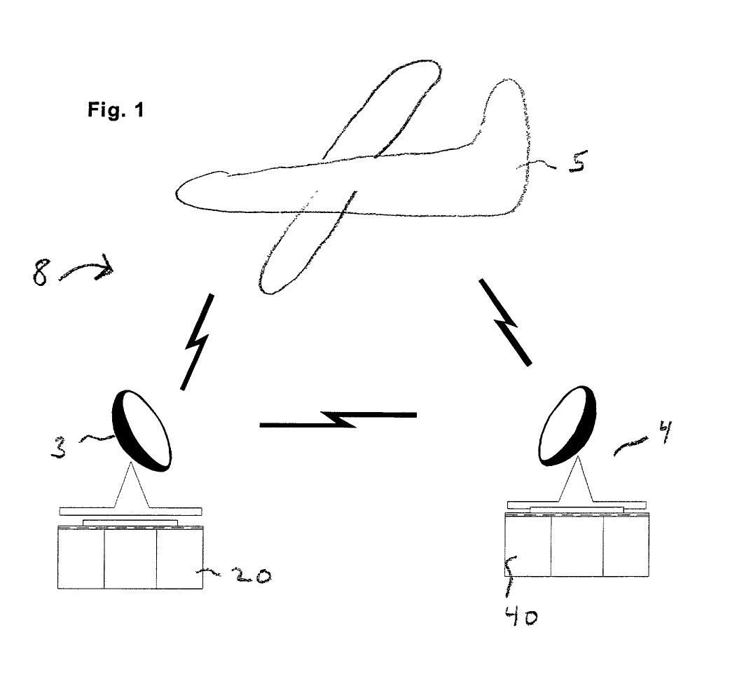

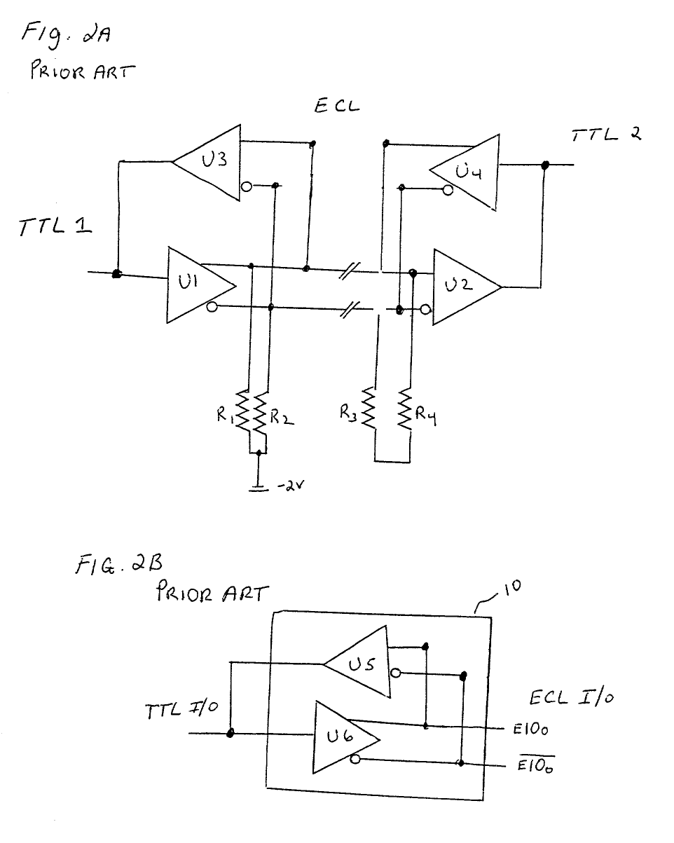

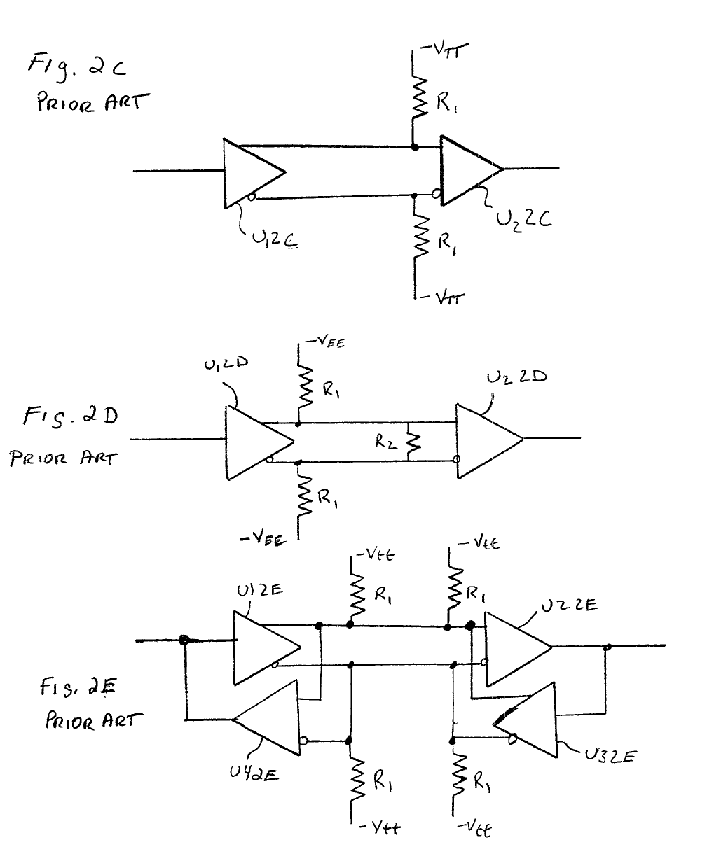

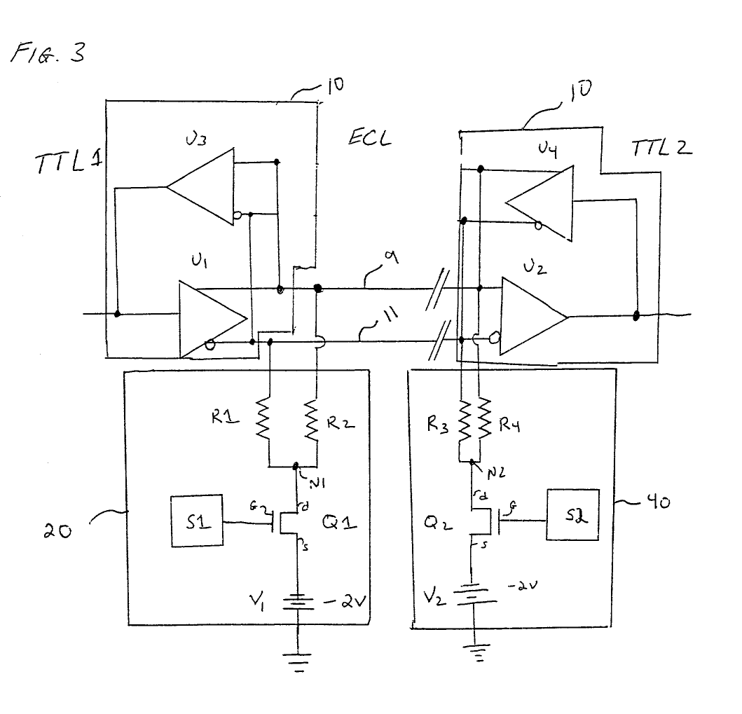

Referring to FIG. 1, a schematic view of a synchronized command link system 8 incorporating features of the present invention is shown. The synchronized command link system 8 comprises an aircraft 5, ground relay facilities 3, and ground relay facilities 4. Devices 20, 40 incorporate features of the present invention and are shown in more detail in FIG. 3. Although the present invention will be described with reference to the embodiments shown in the drawings, it should be understood that the present invention can be embodied in many alternate forms of embodiments. For example, Devices 20, 40 incorporating features of the present invention are generally intended to be used for terminating high frequency signals such as described above with reference to FIG. 1 and other high frequency applications requiring ECL terminators and EMI reduction without physically reconfiguring the ECL terminations (e.g.: communication devices, weapons systems, video devices, or electronic surveillance equipment).

Referring now to FIG. 3 there is shown a schematic diagram of the two devices 20, 40, each incorporating features of the present invention. The devices 20, 40, each comprise: two current resistors R1-R4, generally equivalent to the characteristic impedance of the transmission line, a switch Q1, Q2 and a switch controller S1, S2. The resistors may comprise any material designed to provide a specific amount of resistance to current flow. The resistors may also comprise active components such as active load transistors. Each switch Q1, Q2 is connectable to a voltage supply V₁, V₂ generally −2vdc. Alternatively the voltage supply may be installed in the devices 20, 40, as shown in FIG. 1.

Referring now to device 20. Device 20 comprises resistors R1-R2, generally 50 ohm resistors, each connectable on one end to node N1. The other ends of resistors R1-R2 are connectable to the non-inverted 9 and inverted 11 ECL differential data bus 10, respectively.

Switch controller S1 may be any suitable controller capable of outputting on and off signals to switch Q1. Switch controller S1 may be manually controlled such as an on/off switch or may be controlled by software.

Switch Q1 comprises a field effect transistor. Alternatively, switch Q1 could be any suitable two terminal switch having a control port. Switch Q1 drain d is connectable to node N1 and switch Q1 source s is connectable to V₁. Switch Q1 control port G is controlled by switch controller S1. When switch controller S1 outputs an off signal switch Q1 is in the off or open state, effectively placing resistors R1 and R2 in series between the inverting and non-inverting ECL differential data bus. Thereby terminating the inverting and non-inverting ECL data bus for receive mode. When switch controller S1 outputs an on signal to switch control port g the switch Q1 is conducting and is in the on or shorted state, effectively conducting the −2vdc source V1 to node N1; thereby terminating the inverting 11 and non-inverting 9 ECL data bus for transmit mode.

Referring now to device 40. Device 40 comprises resistors R2-R4, generally 50 ohm resistors, each connectable on one end to node N2. The other ends of resistors R2-R4 are connectable to the non-inverted 9 and inverted 11 ECL differential data bus 10, respectively.

Switch controller S2 may be any suitable controller capable of outputting on and off signals to switch Q2. Switch controller S2 may be manually controlled such as an on/off switch or may be controlled by software.

Switch Q2 comprises a field effect transistor. Alternatively, switch Q2 could be any suitable two terminal switch having a control port. Switch Q2 drain d is connectable to node N2 and switch Q2 source s is connectable to V2. Switch Q2 control port G is controlled by switch controller S2. When switch controller S2 outputs an off signal switch Q2 is in the off or open state, effectively placing resistors R2 and R4 in series between the inverting and non-inverting ECL differential data bus. Thereby terminating the inverting and non-inverting ECL data bus for receive mode. When switch controller S2 outputs an on signal to switch control port g the switch Q2 is conducting and is in the on or shorted state, effectively conducting the −2vdc source V2 to node N2; thereby terminating the inverting 11 and non-inverting 11 ECL data bus for transmit mode.

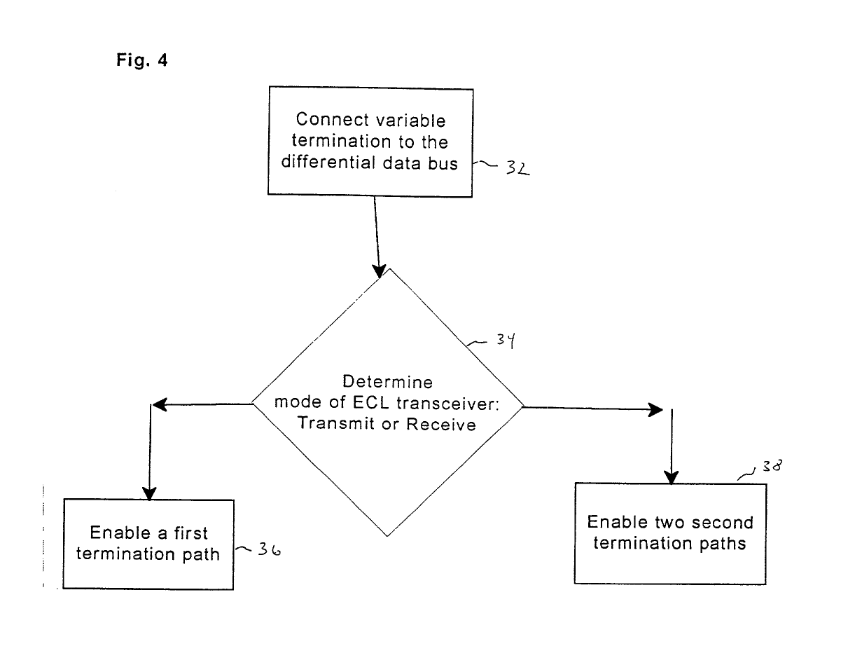

Referring also to FIG. 4, when it is desired that device 10 transmit and received over the same ECL differential data bus devices 20, 40 are connected 32 to the ECL differential data bus. When it is determined 34 that transmitter U1 transmit over the ECL differential data bus and receiver U2 receive, switch controller S1 is set to output an on signal to switch Q1. This condition enables 38 two termination paths and properly terminates the ECL data bus from transmitter U1 for transmit. Switch controller S2 is set to output an off signal to switch Q2. This condition enables 36 a first termination path and properly terminates the ECL data bus into receiver U2 for receive. Similarly, when it is desired that transmitter U4 transmit over the ECL differential data bus and receiver U3 receive, switch controller S1 is set to output an off signal to switch Q1 and switch controller S2 is set to output an on signal to switch Q2. This condition properly terminates the ECL data bus from transmitter U4 for transmit and properly terminates the ECL data bus into receiver U3 for receive.

In the manner described above the invention advantageously allows termination of the ECL data bus to be selected on an as required basis without requiring physical reworking the circuit to add or remove resistors and change connections. In this manner an ECL data bus with an TTL-ECL transceiver may utilize the same ECL differential data bus to transmit and receive ECL data. It is also readily appreciated that the invention may be entirely contained within an integrated circuit such as, for example, an application specific integrated circuit (ASIC) or a field programmable gate array.

It should be understood that the foregoing description is only illustrative of the invention. Various alternatives and modifications can be devised by those skilled in the art without departing from the invention. Accordingly, the present invention is intended to embrace all such alternatives, modifications and variances which fall within the scope of the appended claims.

What is claimed is:

1. A device for changing a termination voltage of a differential data bus, the differential data bus comprising a first data bus and a second data bus, the device comprising:
a first adjustable termination path connectable to the first data bus;
a second adjustable termination path connectable to the second data bus; and
a switch connectable in parallel with the first adjustable termination path and the second adjustable termination path.

2. A device as in claim 1 wherein the differential data bus comprises a differential twisted pair line.

3. A device as in claim 1 wherein the first adjustable termination path is 50 ohm to −2 volts or 100 ohms between the first data bus and the second data bus.

4. A device as in claim 1 wherein the second adjustable termination path is 50 ohm to −2 volts or 100 ohms between the first data bus and the second data bus.

5. A device as in claim 1 wherein the switch is a field effect transistor (FET).

6. A method for changing terminations in an emitter coupled logic (ECL) transceiver having a differential data bus, the method comprising the steps of:
connecting a variable termination to the differential data bus, wherein the variable termination is a first termination path or two second termination paths, the differential data bus having:
a first data bus; and
a second data bus;
enabling the first termination path when the ECL transceiver is in a receive mode; and
enabling the two second termination paths when the ECL transceiver is in a transmit mode.

7. A method as in claim 6 wherein the step of connecting the variable termination to the differential data bus further comprises the step of:
connecting a field effect transistor (FET) to the variable termination, wherein the FET enables the first termination path or the second termination path.

8. A method as in claim 6 wherein the step of enabling the first termination path further comprises the step of configuring the first termination path to be 100 ohms between the first data bus and the second data bus.

9. a method as in claim 6 wherein the step of enabling the two second termination paths further comprises the steps of:
configuring a first one of the two second termination paths to be 50 ohms between the first data bus and a −2vdc source; and
configuring a second one of the two second termination pates to be 50 ohms between the second data bus and the −2vdc source.

10. An apparatus for changing terminations in an emitter coupled logic (ECL) transceiver having a differential data bus, the apparatus comprising:
a variable termination connectable to the differential data bus, the variable termination comprising a first termination path or two second termination paths, the differential data bus having:
a first data bus connectable to the ECL transceiver; and
a second data bus connectable to the ECL transceiver.

11. An apparatus as in claim 10 wherein the variable termination further comprises:
a field effect transistor (FET), wherein the FET enables the first termination path or the second termination path.

12. An apparatus as in claim 10 wherein the first termination path further comprises 100 ohms between the first data bus and the second data bus.

13. An apparatus as in claim 10 wherein the two second termination paths further comprises:
a first one of the two second termination paths to be 50 ohms between the first data bus and a −2vdc source; and
a second one of the two second termination pates to be 50 ohms between the second data bus and the −2vdc source.

14. A device for changing a termination voltage of a differential data bus, the differential data bus comprising a first data bus and a second data bus, the device comprising:
a resistive circuit connecting the first and second data buses to each other; and
a switch circuit located between the resistive circuit and a negative voltage source,
wherein the switch circuit has a connection point with the resistive circuit between two resistors of the resistive circuit, and wherein the switch circuit is operable to selectively connect the first and second data buses, respectively through individual ones of the two resistors, to the negative voltage source.

15. A device as in claim 14 wherein the resistive circuit connecting the first and second data buses to each other further comprises two series connected 50 ohm resistors.

16. A device as in claim 14 wherein the switch circuit located between the resistive circuit and a negative voltage source further comprises a field effect transistor.

17. A device as in claim 14 wherein the negative voltage source further comprises −2vdc.

18. At least one program storage device readable by a machine, tangibly embodying a program of instructions executable by the machine to perform method steps for changing terminations in a programmable logic device (PLD) having a multi-mode data bus, the method comprising the steps of:
connecting a variable termination to the multi-mode data bus, wherein the variable termination is a first termination path or two second termination paths, the multi-mode data bus having:
a first data bus; and
a second data bus;
enabling the first termination path when the PLD is in a receive mode; and
enabling the two second termination paths when the PLD is in a transmit mode.
